(19) United States
(12) Patent Application Publication
(10) Pub. No.: US 2017/0295665 A1
(43) Pub. Date: Oct. 12, 2017

(54) PRE-TERMINATED OVERVOLTAGE PROTECTION MODULE FOR ELECTRONICS CABINET

(71) Applicant: CommScope Technologies LLC, Hickory, NC (US)

(72) Inventors: Charles J. Mann, Omaha, NE (US); Jer-Haw Joseph Yeh, Plano, TX (US); Stephen P. Watson, Richardson, TX (US); Tri H. Nguyen, Richardson, TX (US)

(21) Appl. No.: 15/451,028

(22) Filed: Mar. 6, 2017

Related U.S. Application Data
(60) Provisional application No. 62/319,986, filed on Apr. 8, 2016.

(51) Int. Cl. H05K 7/14; H01R 9/26

(52) U.S. Cl. CPC H05K 7/1492; H05K 7/1489; H01R 9/26

(57) ABSTRACT

An overvoltage protection (OVP) module includes: an OVP assembly comprising a plurality of OVP units; a frame mounted to the OVP assembly; a terminal block with a plurality of first electrical ports and a plurality of second electrical ports, the terminal block mounted to the frame; and a plurality of electrical conductors, each conductor electrically connected between one of the first electrical ports of the terminal block and a respective OVP unit.

### RELATED APPLICATION

The present application claims priority from and the benefit of U.S. Provisional Patent Application No. 62/319,986, filed Apr. 8, 2016, the disclosure of which is hereby incorporated herein in its entirety.

### FIELD OF THE INVENTION

The present invention relates generally to cabinets, and more specifically to electronics cabinets.

### BACKGROUND

Outdoor electronic cabinets have become popular in recent years. They can protect a wide range of electronic equipment including radios, multicarrier power amplifiers (MCPA), power suppliers, batteries, and wireless cell site backhaul equipment. These cabinets can protect base station equipment from environmental conditions while minimizing operating expenses and energy consumption.

In many instances, it is desirable to include overvoltage protection within an electronic cabinet to protect devices mounted in or connected to components within the cabinet. Overvoltage protection may be supplied as an overall assembly that is mounted within the cabinet, with a number of individual overvoltage units included in the assembly. These individual overvoltage units are connected with other devices/components associated with the cabinet to protect then from voltage surges.

It may be desirable to simplify the installation of overvoltage assemblies within an electronics cabinet.

### SUMMARY

As a first aspect, embodiments of the invention are directed to an overvoltage protection (OVP) module, comprising: an OVP assembly comprising a plurality of OVP units; a frame mounted to the OVP assembly; a terminal block with a plurality of first electrical ports and a plurality of second electrical ports, the terminal block mounted to the frame; and a plurality of electrical conductors, each conductor electrically connected between one of the first electrical ports of the terminal block and a respective OVP unit.

As a second aspect, embodiments of the invention are directed to an electronics cabinet, comprising: a cabinet with a front wall, a rear wall and two side walls; mounting racks mounted near the side walls; and an OVP module. The OVP module comprises: an OVP assembly comprising a plurality of OVP units; a frame mounted to the OVP assembly; a terminal block with a plurality of first electrical ports and a plurality of second electrical ports, the terminal block mounted to the frame; and a plurality of electrical conductors, each conductor electrically connected between one of the first electrical ports of the terminal block and a respective OVP unit. The OVP module is mounted to the mounting racks within the cabinet.

As a third aspect, embodiments of the invention are directed to an electronics cabinet, comprising: a cabinet with a front wall, a rear wall and two side walls; mounting racks mounted near the side walls; and an OVP module. The OVP module comprises: an OVP assembly comprising a plurality of OVP units; a terminal block with a plurality of first electrical ports and a plurality of second electrical ports; and a plurality of electrical conductors, each conductor electrically connected between one of the first electrical ports of the terminal block and a respective OVP unit. The OVP assembly is mounted to the mounting racks within the cabinet, and the terminal block is mounted on the walls of the cabinet or the mounting racks.

### BRIEF DESCRIPTION OF THE FIGURES

FIG. 1 is a perspective view of a cabinet according to embodiments of the invention.

FIG. 2 is a perspective view of an overvoltage protection assembly for the cabinet of FIG. 1.

FIG. 3 is a perspective view of an overvoltage module according to embodiments of the invention, shown without cables connected between the overvoltage units and the terminal block.

FIG. 4 is a perspective view of the overvoltage module of FIG. 3 with cables extending between the overvoltage units and the terminal block.

FIG. 5 is a perspective view of two overvoltage modules of FIG. 4 installed in a cabinet similar to that shown in FIG. 1, with a trunk cable connected to one of the overvoltage modules.

FIG. 6 is a schematic perspective views of an overvoltage module according to alternative embodiments of the invention, wherein the terminal block is mounted on a wall of the cabinet.

### DETAILED DESCRIPTION

The present invention is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

Like numbers refer to like elements throughout. In the figures, the thickness of certain lines, layers, components, elements or features may be exaggerated for clarity.

The terminology used herein is for the purpose of describing particular embodiments only and is not intended to be limiting of the invention. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

It will be understood that, when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

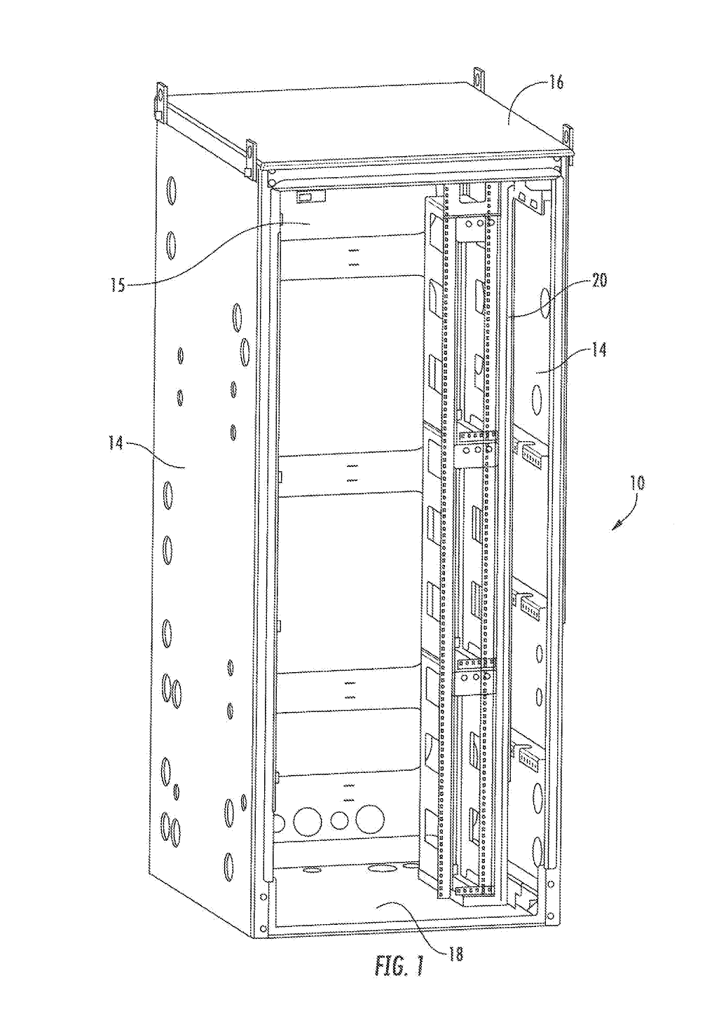

Referring now to the figures, an electronics cabinet, designated broadly at 10, is shown in FIG. 1. The cabinet 10 is generally box-shaped, with a front wall/door (not shown), opposed side walls 14, a rear wall 15 (which includes a number of removable panels 15a that cover access windows), a ceiling 16, and a floor 18. The cabinet 10 may be of conventional construction and need not be described in detail herein. The front wall is typically positioned between about 18 and 28 inches from the rear wall 15. The cabinet 10 is typically between about 60 and 84 inches in height.

A vertical rail 20 is mounted to one of the side walls 14. An opposed vertical side rail (not shown in FIG. 1) is mounted on the opposite side wall 14. A sectioned rack 30 is attached to one of the vertical rails 20; the rack 30, on which is mounted a series of vertical mounting brackets 70, can be adjusted between nominal 19″ and 23″ widths for standard equipment (further detail about the rack 30 is provided in co-assigned U.S. Provisional Patent Application No. 62/311,589, filed Mar. 22, 2016, the disclosure of which is hereby incorporated herein in its entirety). Exemplary equipment/components that may be mounted on the rack 30 and opposed vertical rail include DC power distribution modules, power plants, fiber management features, routers, baseband units, power CWDM units, microwave radios, digital security units, master controllers, optical test units, and the like.

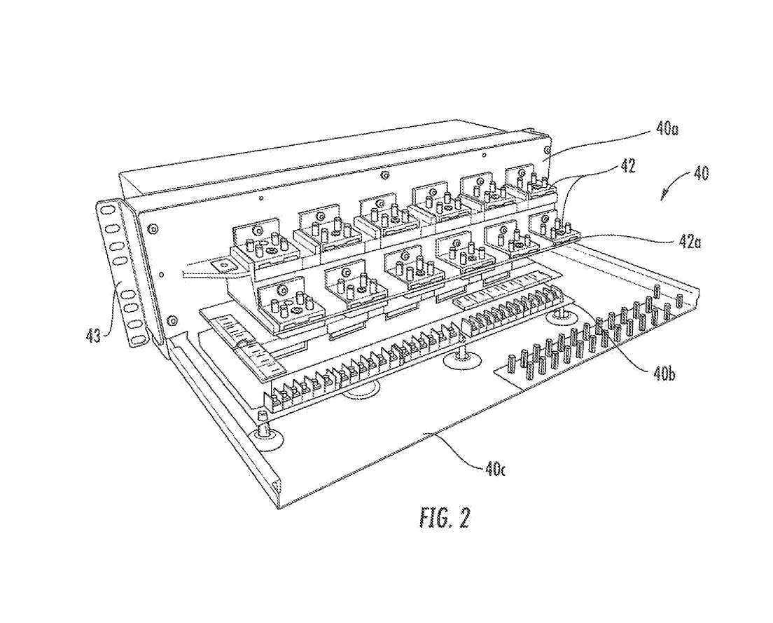

Referring now to FIG. 2, an overvoltage protection (OVP) assembly, designated broadly at 40, is illustrated therein. The OVP assembly 40 includes a plurality of individual OVP units 42 mounted on the rear side of a main housing 40a. A circuit board 40b is mounted below the OVP units 42 and above a tray 40c. Each of the OVP units 42 includes ports 42a configured for electrical connection (typically either to an electrical device housed in the cabinet 10 or to a device remote from the cabinet connected via cables to a connection within the cabinet 10). The OVP units 42 have the capability of creating an electrical shunt away from sensitive electrical components when a threshold voltage is reached. In some embodiments, the OVP units 42 rely on metallic oxide varistors to provide OVP capability. An exemplary overvoltage protection device is the RCMDC-2260-RM-48, available from RayCap, Inc., which is designed to protect up to six −48V DC circuits.

Under typical circumstances, the OVP assembly 40 is electrically connected with multiple components/devices to provide protection against a voltage surge (often due to a lightning strike). For example, the OVP assembly 40 may be connected to an AC load center, a DC rectifier, external remote radio head units (RRUs), and/or other external devices outside of the enclosure that may be subject to potential electrical surges from external sources.

In prior cabinets, the OVP assembly 40 would be installed in a cabinet 10 via side brackets 43 mounted to the vertical mounting brackets 70 of the cabinet 10. The cabinet 10 would be shipped to a remote site (such as the base of an antenna tower), where the cabinet was installed and connections made. The OVP assembly 40 would be mounted in the cabinet 10 on the rack 30 and/or vertical rails 20 with the OVP units 42 facing the rear of the cabinet. A technician would then engage in the laborious task of connecting each individual OVP unit 42 with the appropriate electrical component/device. This task would be performed while the technician reached through an access window 15a in the rear wall 15 of the cabinet. If multiple OVP assemblies 40 were included (which is a common configuration), the task would be repeated for each OVP assembly 40. Typically, this task would take several hours, as the access to the individual OVP units 42 may have been somewhat limited through the access window, other components mounted in the cabinet may have impeded or interfered with access, and the OVP assembly 40 may have been mounted at a height in the cabinet that is not convenient for access through one of the access windows (particularly when multiple OVP assemblies 40 were present).

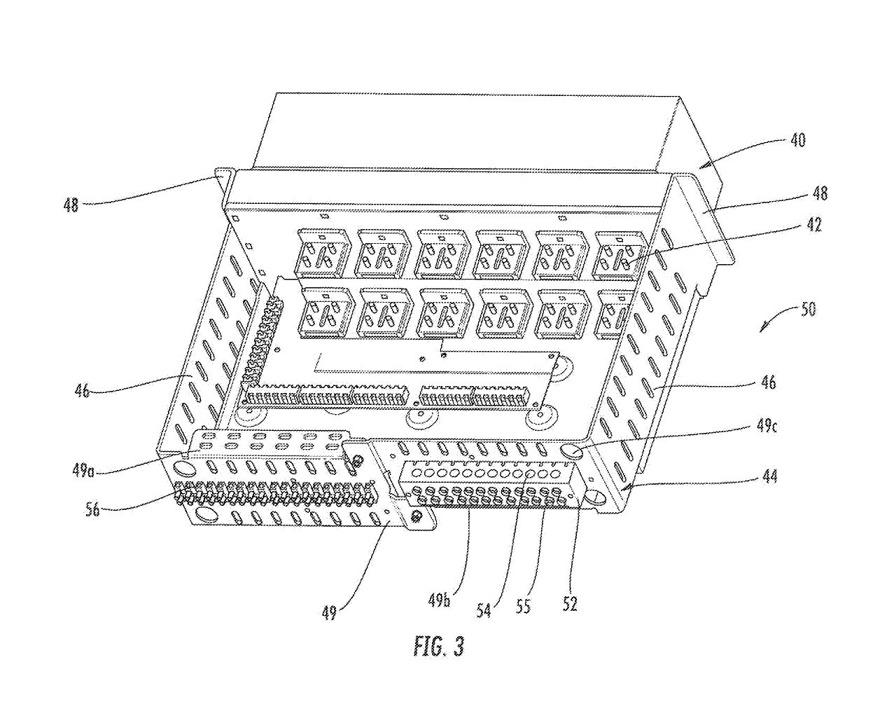

Referring now to FIG. 3, to address the issue of long, tedious and arduous connection of the OVP units 42 to the various devices that require overvoltage protection, an OVP module 50 offers an elegant solution. The OVP module 50 includes an OVP assembly 40 with individual OVP units 42 mounted within a frame 44 that surrounds the tray 40c ; the frame 44 can then be mounted within the cabinet 10. The frame 44 includes side walls 46 with flanges 48 at their forward ends for mounting to the mounting brackets 70 of a cabinet 10.

The frame 44 also includes a rear wall 49 that spans the rear ends of the side walls 46. A terminal block 52 is mounted on the rear surface of the rear wall 49. The terminal block 52 has electrical ports 54 on its top surface and electrical ports 55 on its bottom surface. Also, a series of alternative terminal blocks 56 for smaller gauge alarm wiring are mounted on the lower surface of the rear wall 49. The rear wall 49 includes a lowered top edge 49a above the terminal blocks 56 and a raised lower edge 49b below the terminal block 52 to provide routing lanes for cabling. Holes 49c in the corners of the rear wall 49 also provide cable routing lanes.

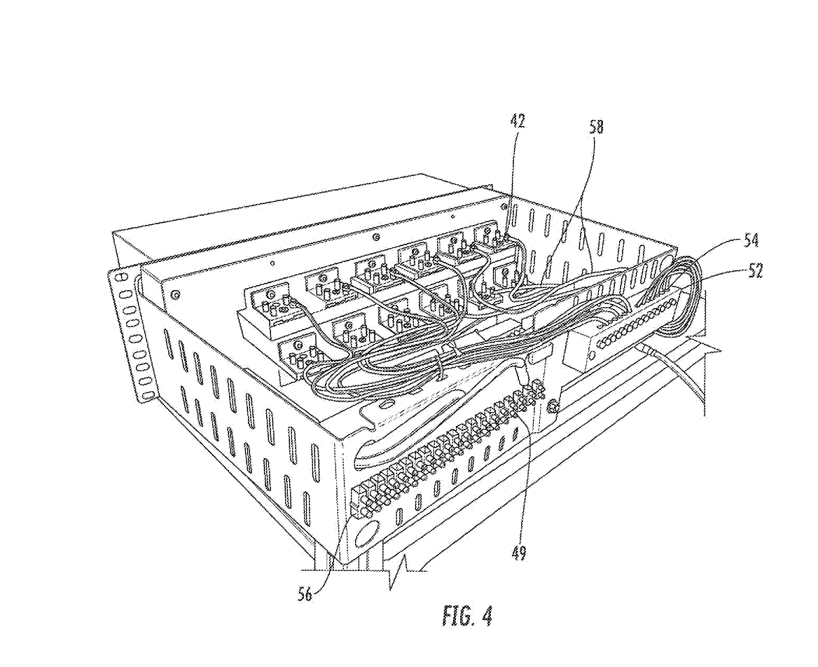

As can be seen in FIG. 4, power cables 58 are routed between each OVP unit 42 and the ports 54 of the terminal block 52. Interconnection of the power cables 58 can be performed in a factory setting, when access to the OVP units 42 is not restricted by the walls of a cabinet or by any interfering object above the OVP module 50. Also, the power cables 58 can be routed/managed between the OVP units 42 and the terminal block 52 in a manner that is organized and convenient. Likewise, alarm cables can be managed to terminal blocks 56 in a similar fashion. The result is a pre-terminated module that can be easily accessed once installed in a cabinet. In addition, the OVP module 50 can be tested in the factory for operability rather than in the field.

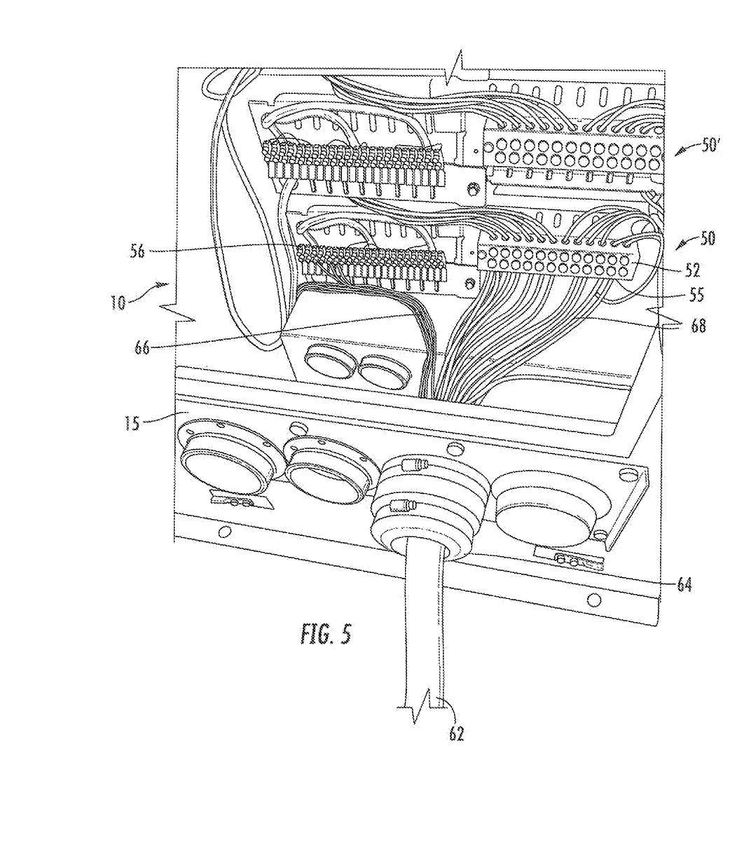

Referring now to FIG. 5, the cabinet 10 includes two OVP modules 50, 50′ installed therein. A hybrid trunk cable 62 enters the rear wall 15 of the cabinet 10 through a cable gland 64. The jacket of the trunk cable 62 is removed from the portion of the trunk cable 62 that is inside the rear wall 15 to expose optical fibers 66 and power conductors 68. The alarm cables 66 from the trunk cable 62 are routed to the terminal blocks 56. The power conductors 68 from the trunk cable 62 are routed and connected to the ports 55 of the terminal block 52. Thus, the power conductors 68 of the trunk cable 62 are connected to the OVP units 42 of the OVP module 50 via the terminal block 52 and the power cables 58. Optical fibers from the trunk cable 62 are routed to a separate fiber storage and management device. It can be easily discerned that connection of the power conductors 68 to the ports 55 of the terminal block 52 is much simpler and less time-consuming than would interconnection of the power conductors 68 to individual OVP units 42 of an OVP assembly 40 that was not part of an overall OVP module 50.

Also, as can be seen in FIG. 5, the use of the pre-terminated OVP modules 50 enables two (or more) OVP modules 50, 50′ to be mounted within the cabinet 10 directly above/below each other, as there is plenty of space adjacent either OVP module 50, 50′ for a technician to interconnect the power conductors 68 and the alarm conductors 66 to the terminal blocks 52 and the alarm terminal blocks 56. This would not be the case for a technician attempting to connect power conductors from a hybrid trunk cable to individual OVP units 42; instead, these require space (typically at least 1 U in height) between OVP assemblies. Because the OVP modules 50, 50′ can be mounted directly above/below each other, valuable space within the cabinet is saved, thereby enabling other equipment to be mounted advantageously within the cabinet 10.

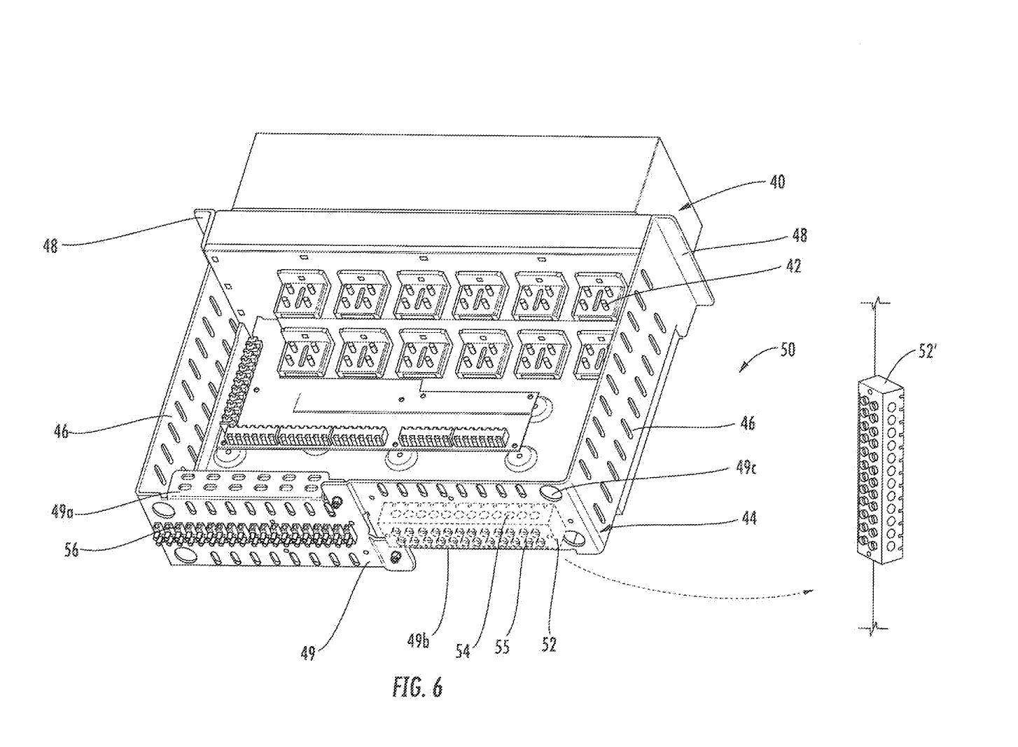

Those skilled in this art will appreciate that, although the terminal block 52 is illustrated mounted to the frame 44 of the OVP module 50, in some embodiments (and as shown in FIG. 6), it may be desirable to mount the terminal block 52′ to one of the walls of the cabinet 10 (wherein mounting the terminal block 52′ to a cabinet wall is intended to encompass mounting the terminal block 52′ to a rigid structure, such as a bracket or rack, that is fixed relative to one of the walls). In such embodiments, the terminal block 52′ may be advantageously located for easy access near an access window, which may be desirable if the OVP module 50 is mounted either very high or very low within the cabinet 10.

The invention being thus described, it will be apparent that the same may be varied in many ways. Such variations are not to be regarded as a departure from the spirit and scope of the invention, and all such modifications as would be obvious to one skilled in the art are to be included within the scope of the following claims.

That which is claimed is:

1. An overvoltage protection (OVP) module, comprising:
an OVP assembly comprising a plurality of OVP units;
a frame mounted to the OVP assembly;
a terminal block with a plurality of first electrical ports and a plurality of second electrical ports, the terminal block mounted to the frame; and
a plurality of electrical conductors, each conductor electrically connected between one of the first electrical ports of the terminal block and a respective OVP unit.

2. The OVP module defined in claim 1, further comprising a plurality of alarm terminal blocks mounted to the frame.

3. The OVP module defined in claim 2, wherein the frame comprises a rear wall, and wherein the terminal block and the alarm terminal blocks are mounted on the rear wall.

4. The OVP module defined in claim 1, wherein the OVP units are all disposed on a first side of the OVP assembly, and wherein the frame is disposed on the first side of the OVP assembly.

5. The OVP module defined in claim 1, further comprising mounting flanges on opposite sides thereof for mounting in an electronics cabinet.

6. The OVP module defined in claim 1, wherein the OVP units are configured to provide protection for −48V DC circuits.

7. The OVP module defined in claim 1, in combination with a trunk cable having a plurality of electrical conductors, wherein each of the electrical conductors is connected to a respective second electrical port of the terminal block.

8. An electronics cabinet, comprising:
a cabinet with a front wall, a rear wall and two side walls;
mounting racks mounted near the side walls; and
an OVP module comprising:
an OVP assembly comprising a plurality of OVP units;
a frame mounted to the OVP assembly;
a terminal block with a plurality of first electrical ports and a plurality of second electrical ports, the terminal block mounted to the frame; and
a plurality of electrical conductors, each conductor electrically connected between one of the first electrical ports of the terminal block and a respective OVP unit.
wherein the OVP module is mounted to the mounting racks within the cabinet.

9. The electronics cabinet defined in claim 8, wherein the terminal block is located adjacent the rear wall of the cabinet.

10. The electronics cabinet defined in claim 9, further comprising a trunk cable routed through the rear wall of the cabinet, the trunk cable including a plurality of power conductors, the power conductors of the trunk cable electrically connected to respective second electrical ports of the terminal block.

11. The electronics cabinet defined in claim 8, further comprising a plurality of alarm terminal blocks mounted to the frame.

12. The electronics cabinet defined in claim 11, wherein the frame comprises a rear wall, and wherein the terminal block and the alarm terminal blocks are mounted on the rear wall.

13. The electronics cabinet defined in claim 8, wherein the OVP units are all disposed on a first side of the OVP assembly, and wherein the frame is disposed on the first side of the OVP assembly.

14. The electronics cabinet defined in claim 8, wherein the frame further comprises mounting flanges on opposite sides thereof for mounting to the mounting rack.

15. The electronics cabinet defined in claim 8, wherein the OVP units are configured to provide protection for −48V DC circuits.

16. The electronics cabinet defined in claim 8, wherein one of the OVP units is connected to an AC load center or a DC power rectifier.

17. The electronics cabinet defined in claim 8, wherein the OVP module is a first OVP module, and further comprising a second OVP module mounted on the mounting racks in the cabinet directly above and immediately adjacent the first OVP module.

18. An electronics cabinet, comprising:
a cabinet with a front wall, a rear wall and two side walls;
mounting racks mounted near the side walls; and
an OVP module comprising:
an OVP assembly comprising a plurality of OVP units;
a terminal block with a plurality of first electrical ports and a plurality of second electrical ports; and
a plurality of electrical conductors, each conductor electrically connected between one of the first electrical ports of the terminal block and a respective OVP unit.
wherein the OVP assembly is mounted to the mounting racks within the cabinet, and wherein the terminal block is mounted on the walls of the cabinet or the mounting racks.
